(19) United States
(12) Patent Application Publication
(10) Pub. No.: US 2006/0061367 A1
(43) Pub. Date: Mar. 23, 2006

(54) Test light/circuit tester

(76) Inventor: Ieon C. Chenn, Laguna Hills, CA (US)

Correspondence Address: STETINA BRUNDA GARRED & BRUCKER, 75 ENTERPRISE, SUITE 250, ALISO VIEJO, CA, 92656, US

(21) Appl. No.: 10/943,673

(22) Filed: Sep. 17, 2004

(51) Int. Cl. G01R 31/00

(52) U.S. Cl. 324/503

(57) ABSTRACT

A test light tool is provided for indicating electrical potential of a test surface of a vehicle D.C, electrical circuit. The test tool comprises a tool body, first, second and third LEDs disposed within the tool body and an indicator circuit connected to the LEDs. First and second connectors are provided, each having a first end connectable to the indicator circuit, and a second end connectable to one of first and second connection surfaces of the vehicle electrical circuit. A probe is provided having a first end in electrical communication with the indicator circuit and a second end extending from the tool body, and engagable to the test surface. The indicator circuit is operative to illuminate the first LED when the connector second ends exhibit an electrical differential therebetween sufficient to power the indicator circuit. The indicator circuit is further operative to selectively illuminate one or both of the second and third LEDs when the probe tip is engaged to the second surface.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND OF THE INVENTION

The present invention relates to devices used to identify the presence of a voltage/ground on wiring and circuits. More particularly, the invention is directed to a device useful to test voltage levels at exposed surfaces of a DC electrical systems, such as used in automotive systems.

Contemporary automotive test lights are commonly used as a tool to check automotive electrical systems. The tool can be used to check voltage levels at exposed surfaces of a variety of circuits and components, such as wiring and connectors, fuses and fusible links, battery and alternator cables, sensors and switches, lighting switches/circuits and accessory switches/circuits. Such devices are typically connected to the vehicle power source, and include a probe that can be selectively touched to a connector or component to determine the electrical status of the component. Contemporary devices typically contain one or more light indicators that illuminate to indicate the electrical potential of the surface to which the probe is touched. If, for example, the test location is at a ground potential, the device may illuminate a ground or low voltage indicator. Where the test location is at another potential, such as 12 volts, the device may operate to illuminate a hot or high voltage indicator.

One contemporary test light/circuit tester is the Model 3810 Tester marketed by Innova Electronics Corporation of Fountain Valley, California. This device includes a single connector, or clamp, which may be connected to either the 12 volt power source or a ground connector. In use, the probe is touched to the test surface to determine if the test surface is at a different potential then the surface that the clamp is engaged to. If so, the probe light will illuminate, indicating the presence of a voltage/ground at the test surface, i.e. that the test surface is at a different electrical potential then the surface to which the connector is engaged.

Another contemporary test light/circuit tester is the Tool Aid Model 28100 tool marketed by S & G Tool Aid Corp. This device includes a pair of connectors, each of which may be connected to surfaces having different relative polarities, i.e. to either ground or a supply voltage, and a probe. As such, the three-wire device accommodates engagement of either connector to ground, or to the supply voltage, while still allowing safe operation of the device. The device also includes a light indicator which illuminates in different colors depending upon the voltage/ground at the surface touched by the probe.

While such contemporary devices are each useful to identify the electrical potential of a test surface, they do not provide the user with an indication that the device is properly connected prior to actually applying the probe to the test surface. Accordingly, unskilled users may experience some trepidation in utilizing the device, for fear that some damage or injury may result from improper connection of the connectors. Such fears are not uncommon and may discourage many unskilled individuals from using such tools, even where the tools are in fact designed to be safe notwithstanding any misconnection by the user. Put otherwise, the absence of a power connect indicator, prior to applying the probe to a test surface, detracts from confident use of the device.

Accordingly, it is desirable to provide a test light/circuit tester that provides a visual indication that the device is properly connected to operate before the user engages the probe to a test surface. It is further desirable that such a device also incorporates a plurality of light colors or light conditions to indicate the relative potential of the test surface to which the probe is then applied. As such, a user can first be reassured that the device is properly connected before applying the probe to a test surface, and become acclimated to operation of the light indicators before proceeding with the potentially tedious task of applying the probe to a test surface. As the probe is then applied to a test surface the tester will then selectively generate a visual indication representative of the potential of the test surface, e.g. positive or ground, without having to reverse the connectors.

### BRIEF SUMMARY OF THE INVENTION

A test light tool is provided for indicating electrical potential of a test surface of a vehicle D.C, electrical circuit. The test tool comprises a handheld tool body, first, second and third LEDs disposed within the tool body and an indicator circuit connected to the LEDs. First and second connectors are provided, each having a first end connectable to the indicator circuit, and a second end connectable to one of first and second connection surfaces of the vehicle electrical circuit. A probe is provided having a first end in electrical communication with the indicator circuit and a second end, typically extending from the tool body, and engagable to the test surface. The indicator circuit is operative to illuminate the first LED when the connector second ends exhibit an electrical differential therebetween sufficient to power the indicator circuit. The indicator circuit is further operative to selectively illuminate one of the second and third LEDs when the probe tip is engaged to the second surface.

The indicator circuit is operative to illuminate the first and second LED when the test surface is at ground, or some other negative potential relative to the potential of the first connection surface.

The indicator circuit is operative to illuminate the first and third LED when it is connected to 12 volts, or a positive electrical potential relative to the potential of the second connection surface.

The indicator circuit is operative to illuminate the first, second and third LEDs when the test surface is at a negative potential relative to the first connection surface and a positive electrical potential relative to the second connection surface.

In use, the first connection surface may be a battery positive terminal and the second connection surface may be the battery negative terminal or a ground location within the vehicle electrical circuit. In such a configuration, the electrical differential between the first and second connection surfaces is approximately 12 volts. However, the indicator circuit may be operative with less then 12 volts differential between the first and second connection surfaces.

### BRIEF DESCRIPTION OF THE DRAWINGS

FIG. 1 illustrates one embodiment of a handheld test light/circuit tester formed in accordance with the present invention;

FIG. 2 is a exemplary circuit diagram of the device illustrated at FIG. 1;

FIG. 3a is a circuit diagram showing the circuit for illuminating a first (white) light, indicating that the connectors are properly engaged to operate the tester;

FIG. 3b is a circuit diagram indicating illumination of a second (green) light, indicating that the probe is engaged to test surface having a ground or relative negative potential;

FIG. 3c is a circuit diagram for the circuit illuminating a third (red) light, indicating that the probe is engaged to a surface having a relative positive potential;

FIG. 4 is a top view of a wiring diagram showing the physical arrangement of components of an exemplary circuit disposed on a circuit board locatable within the probe housing; and

FIG. 5 is a bottom view of the wiring diagram of FIG. 4, illustrating the connectivity pattern for connecting the components to the electrical circuit board.

FIG. 6 illustrate another embodiment of a handheld tester constructed in accordance with the present invention.

FIG. 7a-e illustrate another embodiment of a handheld tester constructed in accordance with the present invention.

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

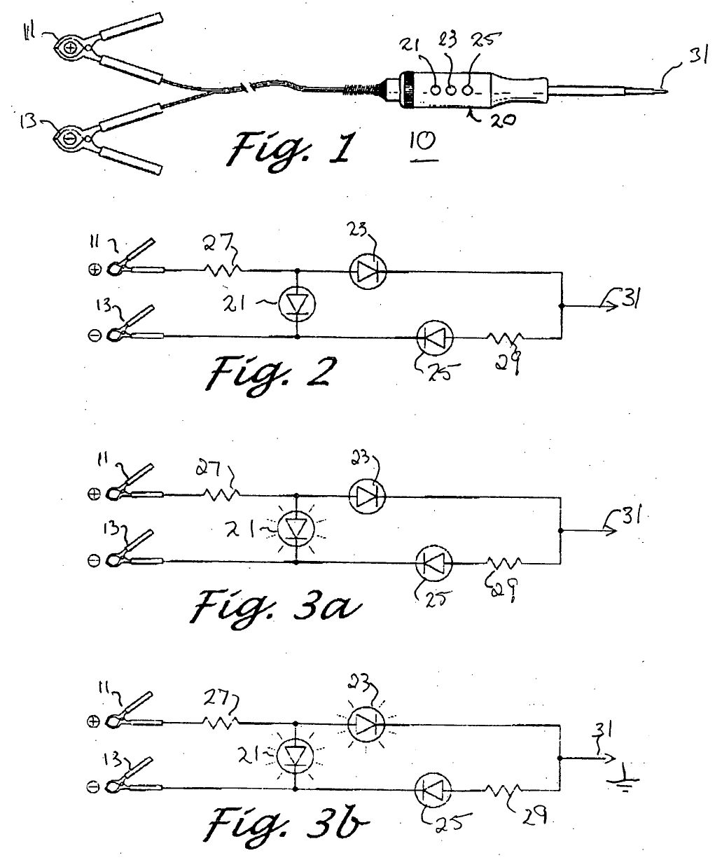

In general, the invention is directed to a test light/circuit tester 10 that operates to provide an indication that the device is properly connected to power source, to properly operate the tester, before the test probe is applied to a test surface. Referring to FIG. 1, in the presently preferred embodiment the tester 10 includes three separate indicators or lights mounted on tester body 20. The first (white) light 21 provides confirmation that the tester device is properly connected to the power source, or to surfaces having a voltage differential therebetween. In the presently preferred embodiment the connectors 11, 13 must be properly connected to associated relative positive and negative voltages for the circuit to properly operate, i.e. for the white light to illuminate. The second (green) light 23 provides an indication that the probe is applied to a test surface having a first potential, e.g. positive 12 volts. The device also includes a third (red) light 25, which indicates that the probe is applied to a test surface having a second electrical potential, e.g. ground level. Lights 21, 23, 25 may be implemented as light emitting diodes. Referring to FIGS. 2-5, load resistors 27, 29 limit current flow in the tester, and may be selected in combination with selection of lights 21, 23, 25 to define voltage levels at which the lights will illuminate.

In practice the user, therefore, first engages the connectors across the power supply, or to connective locations. As shown at FIG. 3a. the device will illuminate a first indicator, e.g. a white light, indicating that the connectors are properly connected to terminals having the correct relative plurality, and that the probe is safe to use. This typically means that one connector is electrically connected to a surface having a relative positive, e.g. 12 volt, potential, and the other connector is electrically connected to a surface having a ground or relative negative potential.

As noted above, in one embodiment of the invention the connectors 11, 13 must be connected to surfaces having a predetermined relative potential, e.g. connector 11 to positive and connector 13 to ground or relative negative. If not, the white light 21 will not illuminate. Such failure to illuminate light 21 indicates that the connectors need to be reversed, or connected to other surfaces.

In another embodiment (not illustrated) the connectors need not be engaged to surfaces that are at predetermined relative polarities. In this embodiment the white light indicates that both connectors are in proper electrical communication with the two contact surfaces, (i.e. the connection in good electrical contact), and that the contact surfaces are at different, through relatively variable electrical polarities. Illumination of the white light 21 will occur, therefore, regardless of the polarity of the surface that either connector is engaged to, as long as good contact is made.

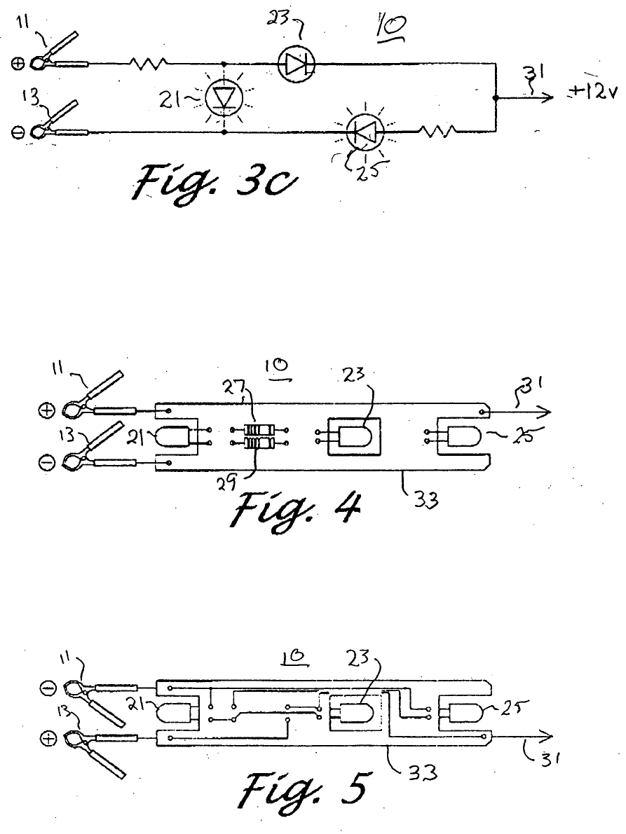

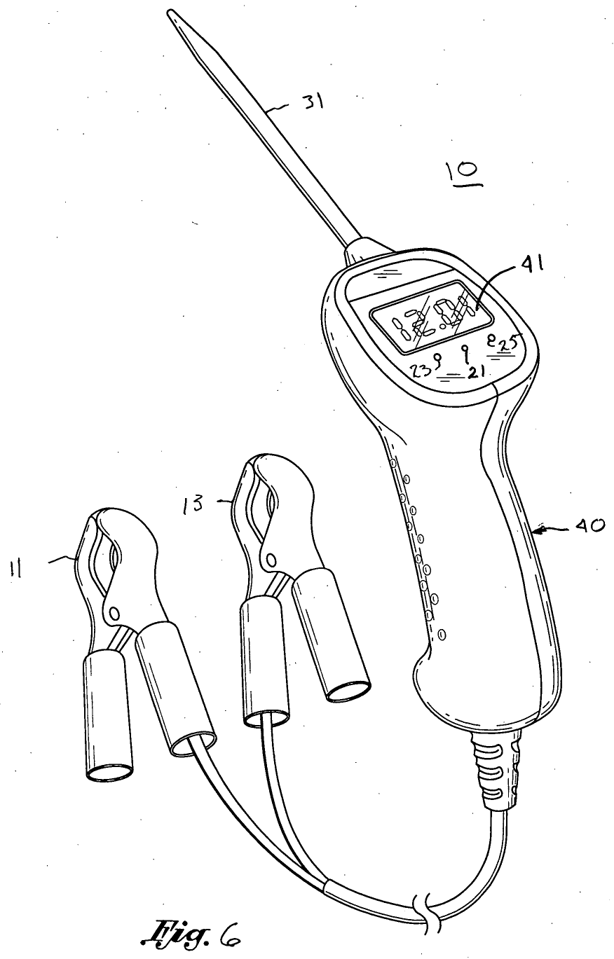

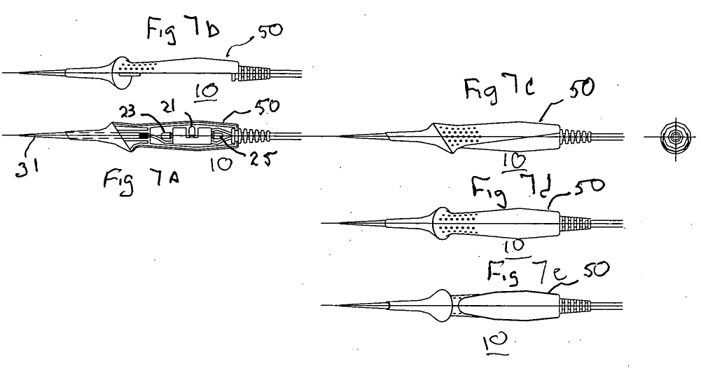

Once the user sees the white light 21 is illuminated, the user is then reassured that connections have been properly made, in accordance with the particular embodiment, and the probe may be used. As shown at FIG. 3b, if the probe 31 is then touched to a location having a ground or relative negative potential, an associated light, e.g. a green light 23, will be illuminated. Alternately, as shown at FIG. 3c, if the probe is touched to a test surface having a relative positive potential, e.g. 12 volts, then another light, e.g. a red light 25, will illuminate. The white light 21 remains illuminated in either case, indicating that the device is properly connected to power the tester 10, and the probe 31 may be operatively applied to a test surface to indicate the surface voltage level. Top and bottom views of a wiring diagram for mounting the tester circuit on a mounting board 33 as shown at FIGS. 4 and 5, respectively.

Where the probe 31 is touched to a surface having potential of ground or 12 volts, only one of the red or green lights 23, 25 will be illuminated, as indicated above. However, where the probe is touched to a test surface having a potential between ground and 12 volts, e.g. 6 volts, then all three lights 21, 23, 25 may be illuminated, i.e. red, green and white lights. The illumination of all three lights may be useful to indicate that a diagnostic condition exists, whereupon further testing and evaluation may be necessary to determine the condition of the test surface. The illumination of all three lights may alternately indicate a condition appropriate to certain circuit components, or surfaces that are normally characterized by a potential that would cause illumination of all three indicator lights. Test surfaces associated with components such as ignition modules, and sensor reference voltages are typically characterized by a potential between ground and 12 volts.

As one of ordinary skill in the art will recognize, the particular voltage levels at which the red and/or green lights will illuminate may be a matter of design choice, implemented by selection of the light emitting diodes 21, 23, 25 and the load resisters 27, 29. By selection of the light emitting diodes and the load resisters the voltage levels at which the red and/or green lights illuminate may be specified for particular applications.

As will be further recognized by those of ordinary skill in the art, these and other variations and enhancements of the above described invention may be implemented without the party from the broader aspects of the invention, as set forth in the appended claims.

Accordingly, with white light confirms that the device is properly connected to receive power to properly operate. The test probe will then illuminate the appropriate voltage level indicator to indicate the relative plurality of the test surface voltage.

FIG. 6 is perspective view of one embodiment of the handheld test light/circuit tester formed in accordance with the present invention.

Shown therein the tester 10 includes a handheld test body 40, formed as a pistol grip, and a probe 31 extending therefrom. A display is formed on the surface of the test body, which is in electrical communication with probe 31 and operates to display information such as voltage level detected at surface engaged by the probe, and indicator lights 21, 23, 25, which may be implemented as white, green and red lights respectively, as indicated above.

Connectors 11, 13 are engaged to the test body, and in electrical communication with an indicator circuit disposed within the test body. The battery power circuit, e.g. to power the display and indicators, will also be disposed within the test body. Alternatively, power may be derived from surfaces to which the connectors are attached.

FIGS. 7a-e illustrate another embodiment of the tester 10 including a handheld body 50 formed as a segmented member of the indication circuit and light indicators formed along the inner segmented surface of the tool.

As will be apparent to those skilled in the art, a test light/circuit tester made in accordance with the present invention can be implemented and incorporate a variety of different types of test bodies, displays and indicators without departing from the broader aspects of the present invention.

What is claimed is:

1. A test light tool for indicating the electrical potential of a test surface of a vehicle D.C. electrical circuit, comprising:
a handheld tool body;
first, second and third light emitting diodes (LEDs) disposed within the tool body;
an indicator circuit connected to the LEDs;
first and second connectors, each of the connectors having a first end connectable to the indicator circuit and a second end connectable to one of the first and second connection surfaces of the vehicle electrical circuit; and
a probe having a first end in electrical communication with the indicator circuit and a second end extending from the tool body and engagable to the test surface;
the indicator circuit being operative to illuminate the first LED when the when the first and second connection surfaces have an electrical differential therebetween sufficient to power the indicator circuit; and
the indicator circuit further being operative to selectively illuminate one of the second and third LEDs when the probe tip is engaged to the test surface.

2. The test light as recited in claim 1 wherein the indication circuit is operative to illuminate the first LED only when the first and second connection surface are at a predetermined relative electrical potential.

3. The test light tool as recited in claim 2 wherein the indicator circuit is operative to illuminate the first and second LED when the test surface is at a negative potential relative to the first connection surface.

4. The test light tool as recited in claim 3 wherein the indicator circuit is operative to illuminate the first and third LEDs when the test surface is at a positive electrical potential relative to the second connection surface.

5. The test light tool as recited in claim 4 wherein the indicator circuit is operative to illuminate the second and third LEDs when the test surface is at a negative potential relative to the first connection surface and a positive electrical potential relative to the second connection surface.

6. The test light tool as recited in claim 5 wherein the indicator circuit is operative to illuminate the first, second and third LEDs when the test surface is at a negative potential relative to the first connection surface and a positive electrical potential relative to the second connection surface.
